(19) United States
(12) Patent Application Publication
(10) Pub. No.: US 2006/0138681 A1
(43) Pub. Date: Jun. 29, 2006

(54) Substrate and lithography process using the same

(75) Inventors: Keith Frank Best, Prunedale, CA (US); Joseph J. Consolini, Costa Mesa, CA (US); Alexander Friz, San Jose, CA (US); Rodney Chisholm, Sungnam-Si (KR)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 11/055,704

(22) Filed: Feb. 11, 2005

Related U.S. Application Data
(60) Provisional application No. 60/638,514, filed on Dec. 27, 2004.

(51) Int. Cl. H01L 21/76; H01L 23/544

(52) U.S. Cl. 257/797; 438/401; 438/462; 438/975

(57) ABSTRACT

Provided are substrates, e.g. semiconductor wafers, whereby the front side of the substrate and the back side of the substrate differ in surface roughness. Also provided are lithography processes using the substrates.

### CROSS-REFERENCE TO RELATED APPLICATIONS

This application claims the benefit of U.S. provisional application 60/638,514, which was filed on Dec. 27, 2004, and which is hereby incorporated in its entirety by reference.

### FIELD

The present invention relates to substrates, e.g. semiconductor wafers, and to processes, e.g. lithography processes, using the same.

### BACKGROUND

Performing alignment via the back side of a wafer in lithography processes is gaining popularity due to the various advantages it can provide, e.g. reduced marker degradation, more freedom in design, and/or a decrease in process steps. However, the double-sided highly polished wafers typically being used are comparatively costly. Also, the high back side surface smoothness of such wafers may lead to undesired sticking of the back side to the table supporting the wafer during lithographic exposure. In addition, the removal of certain impurities from the wafer by so-called gettering can be comparatively ineffective for double-sided highly polished wafers.

Objectives of the present invention include addressing one or more of the above-noted concerns.

Back side alignment is mentioned in, e.g., U.S. Pat. No. 6,768,539, which is hereby incorporated in its entirety by reference. Alignment marks are mentioned in, e.g., U.S. Pat. Nos. 5,503,962; 6,601,314; and 6,140,741; and U.S. Published Application 2004-0130690.

### SUMMARY

In one embodiment, the present invention provides double-sided polished substrates, e.g. semiconductor wafers, whereby the two sides differ in the degree of polishing. One side is polished to a comparatively high degree suitable for creating micropatterns through a lithography process, the other side is polished to a comparatively low degree yet still suitable for providing effective alignment marks to align the wafer during the lithography process.

In one embodiment, the present invention provides substrates, e.g. semiconductor wafers, having a front side and a back side, said front side having a smoother surface than said back side, wherein said back side comprises one or more alignment marks.

In one embodiment, the present invention provides substrates, e.g. semiconductor wafers, having a front side and a back side, said front side having a surface roughness of less than 50 nm, said back side having a surface roughness in the range of 75-250 nm.

In one embodiment, the present invention provides a substrate having a front side and a back side, said back side having a surface roughness of at least 50 nm, said back side comprising one or more alignment marks.

In one embodiment, the present invention provides a device manufacturing lithography process comprising exposing a substrate to radiation, said substrate having a surface facing said radiation and a surface facing away from said radiation, said surface facing said radiation being smoother than said surface facing away from said radiation, said surface facing away from said radiation comprising one or more alignment marks.

In one embodiment, the present invention provides a process comprising:

(i) aligning a substrate having a front side and a back side to a reticle or an array of individually programmable elements;

(ii) patterning a beam of radiation with said reticle or said array of individually programmable elements; and

(ii) exposing the front side of said substrate, or a resist layer provided on said front side of said substrate, to the patterned beam of radiation;

wherein said front side has a smoother surface than said back side;

wherein said front side comprises one or more alignment marks;

wherein said aligning is effected by imaging one or more of said one or more alignment marks via the back side of the wafer.

In one embodiment, the present invention provides a process comprising providing the back side of a substrate having a front side and a back side with one or more alignment marks, wherein said front side has a smoother surface than said back side.

Additional objects, advantages and features of the present invention are set forth in this specification, and in part will become apparent to those skilled in the art on examination of the following, or may be learned by practice of the invention. The inventions disclosed in this application are not limited to any particular set of or combination of objects, advantages and features. It is contemplated that various combinations of the stated objects, advantages and features make up the inventions disclosed in this application.

### BRIEF DESCRIPTION OF THE DRAWINGS

FIG. 1 represents an embodiment of a lithographic projection apparatus.

FIG. 2 represents an embodiment of a substrate table suitable for alignment via the back side of a substrate.

FIGS. 3 and 4 represent an embodiment of alignment optics and a substrate table suitable for alignment via the back side of a substrate.

FIG. 5 represents an example of an alignment mark.

FIG. 6 represents an embodiment of a substrate table suitable for alignment via the back side of a substrate.

FIG. 7 represents an embodiment of a substrate table suitable for alignment via the back side of a substrate.

### DETAILED DESCRIPTION

In one embodiment, the present invention provides double-sided polished substrates, e.g. wafers, whereby the two sides differ in the degree of polishing. One side is polished to a comparatively high degree suitable for building micropatterns (e.g. microcircuits) through a lithography process, the other side is polished to a comparatively low degree yet still suitable for providing effective alignment marks to align the substrate during the lithography process.

The manner of polishing may vary and can be done, e.g., mechanically, chemically, or by a combination thereof. In one embodiment, both sides of the substrate are polished to a certain degree after which one side is further polished to a higher degree. In one embodiment, one side is polished to a high degree after which the other side is polished to a lesser degree. In one embodiment, one side is polished to a certain degree after which the other side is polished to a higher degree. Furthermore, the present wafers may be prepared by polishing both sides of the wafer to a high degree and subsequently roughing one side of the wafer. Polishing methods are discussed in, e.g., U.S. Pat. Nos. 6,709,981; 6,645,862; 6,530,826; 5,980,361; 6,338,805; and 5,571,373. In one embodiment, at least the back side of the substrate is polished by a method using grinding wheels. Grinding wheels are sold, e.g., by Disco Corporation. In one embodiment, the grinding wheels have a grit of at least 1500, e.g. at least 3000, at least 4500, at least 6000, at least 7500, about 8000 or more.

The acceptable roughness of the front side of the substrate may vary and, to an extent, may depend, e.g., on the dimensions of the structures to be created on the semiconductor wafer. In one embodiment, the roughness of the front side surface (highest peak to deepest valley height difference on the wafer surface) is less than 50 nm, for instance less than 30 nm, less than 10 nm, less than 5 nm, less than 3 nm, or less than 1.5 nm. In one embodiment, the surface roughness is at least 0.25 nm.

The acceptable roughness of the back side of the substrate may vary and, to an extent, may depend, e.g., on the type/size/depth of the alignment mark(s) that may be provided on the back side, the wavelength of the radiation used in the alignment procedure, and/or the kind of alignment system being used. In one embodiment, the roughness is at most 900 nm, for instance at most 750 nm, at most 600 nm, at most 500 nm, at most 400 nm, at most 300 nm, at most 250 nm, at most 200 nm, or at most 100 nm. A certain minimum degree of roughness may assist in avoiding sticking of the substrate to, e.g., a substrate support table and/or assist in providing more efficient gettering. Accordingly, in one embodiment, the roughness is at least 50 nm, for instance at least 75 nm, at least 100 nm, at least 150 nm, at least 200 nm, or at least 250 nm. In one embodiment, the back side surface roughness is about 140 nm. The surface roughness (peak to valley height difference on the wafer surface) may be determined, e.g., with a KLA-Tencor P2 apparatus. In one embodiment, the back side of the substrate, e.g. due to its comparatively high surface roughness, is unsuitable for the creation of micropatterns (e.g. microcircuits) through (micro)lithography.

As noted, the acceptable surface roughness may depend on the alignment system being used. For instance, in certain embodiments, so-called through-the-lens (TTL) alignment may be more sensitive to the surface roughness than so-called broad band illumination alignment or pattern recognition alignment. For instance, even though TTL alignment using radiation with 633 nm wavelength may in certain embodiments be ineffective for aligning to phase grating markers on the back side of a substrate where the back side has a surface roughness of about 1 micron or more, other alignment systems and/or wavelengths may still be effective. In one embodiment, the alignment system allows for aligning to alignment marks provided on the non-polished side of a single side polished (SSP) wafer. In one embodiment, the present substrate is a SSP wafer comprising one or more alignment marks on the non-polished side of the wafer. In one embodiment, the present substrate is a substrate having a back side surface roughness of about 1 micron or more wherein the backside comprises one or more alignment marks.

In one embodiment, areas on a side of the substrate differ in the degree of surface roughness. For instance, the substrate may on the back side comprise one or more areas encompassing one or more alignment marks, whereby these areas have a lower surface roughness than areas on the backside that do not encompass one or more alignment marks.

The thickness of the substrate may vary and, to an extent, may depend, e.g., on the substrate material and/or the substrate dimension. In one embodiment, the thickness is at least 50 μm, for instance at least 100 μm, at least 200 μm, at least 300 μm, at least 400 μm, at least 500 μm, or at least 600 μm. In one embodiment, the thickness of the wafer is at most 2500 μm, for instance at most 1750 μm, at most 1250 μm, at most 1000 μm, at most 800 μm, at most 600 μm, at most 500 μm, at most 400 μm, or at most 300 μm.

In one embodiment, the substrate is a wafer, for instance a semiconductor wafer. In one embodiment, the wafer material is selected from the group consisting of Si, SiGe, SiGeC, SiC, Ge, GaAs, InP, and InAs. In one embodiment, the wafer is a III/V compound semiconductor wafer. In one embodiment, the wafer is a silicon wafer. In one embodiment, the substrate is a ceramic substrate. In one embodiment, the substrate is a glass substrate. In one embodiment, the substrate is a plastic substrate.

The shape of the substrate may vary. In one embodiment, the substrate has a substantially circular shape, optionally with a notch and/or a flattened edge along part of its perimeter. In one embodiment, the substrate has a polygonal shape, e.g. a rectangular shape. In one embodiment, the substrate has a diameter of at least 25 mm, for instance at least 50 mm, at least 75 mm, at least 100 mm, at least 125 mm, at least 150 mm, at least 175 mm, at least 200 mm, at least 250 mm, or at least 300 mm. In one embodiment, the substrate has a diameter of at most 500 mm, at most 400 mm, at most 350 mm, at most 300 mm, at most 250 mm, at most 200 mm, at most 150 mm, at most 100 mm, or at most 75 mm.

In one embodiment, the substrate is provided with one or more alignment marks on at least the back side of the substrate. In one embodiment, only the back side comprises one or more alignment marks. In one embodiment, both the back side and the front side of the substrate comprise one or more alignment marks. In one embodiment, the back side (and optionally front side) comprises one or more alignment marks having a phase grating, e.g. two or more alignment marks, for instance 2-20 alignment marks, 2-10 alignment marks, 2-6 alignment marks, 2-4 alignment marks, or 2 alignment marks. In one embodiment, the marks are etched into the substrate. The depth of the grating into the substrate surface (“pitch depth”) may vary and to an extent may depend, e.g., on the tolerances of the alignment scheme of the lithographic apparatus used to create micropatterns on the substrate. In one embodiment, the depth of the grating is less than 400 nm, for instance less than 350 nm, less than 300 nm, less than 250 nm, less than 200 nm, less than 160 nm, or less than 125 nm. In one embodiment, the depth of the grating is at least 50 nm, for instance at least 75 nm, at least 100 nm, at least 150 nm, at least 200 nm, or at least 250 nm. In one embodiment, the pitch depth is about 160 nm. In one embodiment, the alignment mark pitch depth exceeds the back side surface roughness.

In one embodiment, one or more alignment marks are provided on the front side of the substrate, whereby the alignment marks can be imaged via the back side of the substrate. For instance, when the substrate is a silicon substrate, alignment marks on the front of the substrate may be imaged via the back side using infra red radiation (silicon is transmissive to infra red radiation). See also U.S. Pat. No. 6,768,539, FIGS. 9-10 and accompanying text (hereby incorporated by reference in its entirety). In one embodiment, one or more of the one or more alignment marks on the front side of the substrate is provided with an infra red reflective coating. In one embodiment, the back side of the wafer is absent alignment marks.

In one embodiment, a resist coating is provided on the front side of the substrate (the above-noted front side surface roughness values refer to the surface roughness prior to application of the resist coating).

In one embodiment, the present substrates are used in a device manufacturing process, e.g. a lithography process. In one embodiment, a resist layer on the front side of the substrate is exposed to radiation, e.g. e-beam radiation or UV radiation. In one embodiment, the radiation has a wavelength of at least 5 nm, e.g. at least 10 nm, at least 50 nm, at least 100 nm, at least 150 nm, at least 200 nm, at least 250 nm, at least 300 nm, at least 350 nm, or at least 360 nm. In one embodiment, the radiation has a wavelength of at most 450 nm, e.g. at most 400 nm, at most 375 nm, at most 360 nm, at most 300 nm, at most 275 nm, at most 225 nm, at most 175 nm, at most 100 nm, at most 50 nm, or at most 20 nm.

In one embodiment, the present invention provides a process comprising providing the back side of a substrate having a front side and a back side with one or more alignment marks, wherein the front side has a smoother surface than the back side. In one embodiment, the process is a lithographic process. For instance, the process may include applying a layer of resist on the back side, exposing the layer of resist to a patterned beam of radiation, whereby the patterned beam of radiation provides on said resist layer an image of, e.g., one or more of said one or more alignment marks. In one embodiment, the process for providing one or more alignment marks on the back side comprises etching one or more of the one or more alignment marks into the back side. In one embodiment, one or more of the alignment marks are provided by an imprinting process.

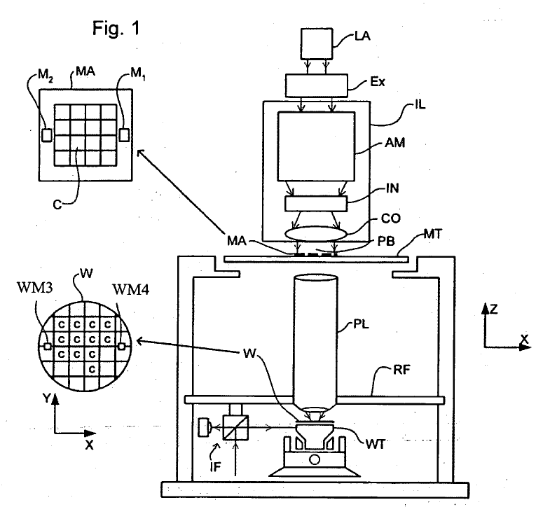

FIG. 1 schematically depicts an embodiment of a lithographic projection apparatus for illuminating a substrate, e.g. a wafer (W), according to the present invention. The apparatus comprises:

a radiation system LA, Ex, IL, for supplying a projection beam PB of radiation (e.g. UV radiation);

a first object table (mask table) MT for holding a mask MA (e.g. a reticle), and connected to first positioner for accurately positioning the mask with respect to item PL;

a second object table (substrate table) WT for holding the wafer W, and connected to second positioner for accurately positioning the substrate with respect to item PL;

a projection system (“lens”) PL (e.g. a quartz lens system, catadioptric or mirror system) for imaging an irradiated portion of the mask MA onto a target portion C (comprising one or more dies) of the wafer W.

As here depicted, the apparatus is of a transmissive type (i.e. has a transmissive mask). However, in general, it may also be of a reflective type (with a reflective mask), for example. Alternatively, the apparatus may employ another kind of patterning device, such as an array of individually controllable elements (e.g. a spatial light modulator such as a micro-mirror device or a grating light valve).

The radiation system comprises a source LA (e.g. a UV laser or a plasma source) that produces a beam of radiation. This beam is fed into an illumination system (illuminator) IL, either directly or after being passed through conditioning optical elements, such as a beam expander Ex, for example. The illuminator IL comprises adjustable optical elements AM for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam PB impinging on the mask MA has a desired uniformity and intensity distribution in its cross-section.

The source LA may be within the housing of the lithographic projection apparatus (as is often the case when the source LA is a mercury lamp, for example), but that it may also be remote from the lithographic projection apparatus, the radiation beam which it produces being led into the apparatus (e.g. with the aid of suitable directing mirrors); this latter scenario is often the case when the source LA is an excimer laser.

The beam PB subsequently intercepts the mask MA which is held in a mask holder on a mask table MT. Having traversed the mask MA, the beam PB passes through the lens PL, which focuses the beam PB onto a target portion C of the wafer W. With the aid of the second positioners (and interferometric measuring system IF), the substrate table WT can be moved accurately, e.g. so as to position different target portions C in the path of the beam PB. Similarly, the first positioner can be used to accurately position the mask MA with respect to the path of the beam PB, e.g. after mechanical retrieval of the mask MA from a mask library, or during a scan. In general, movement of the object tables MT, WT will be realized with the aid of a long stroke module (coarse positioning) and a short stroke module (fine positioning), which are not explicitly depicted in FIG. 1. However, in the case of a wafer stepper (as opposed to a step-and-scan apparatus) the mask table MT may just be connected to a short stroke actuator, or may be fixed.

The depicted apparatus can be used in at least two different modes:

1. In step mode, the mask table MT is kept essentially stationary, and an entire mask image is projected in one go (i.e. a single “flash”) onto a target portion C. The substrate table WT is then shifted in the x and/or y directions so that a different target portion C can be irradiated by the beam PB;

2. In scan mode, essentially the same scenario applies, except that a given target portion C is not exposed in a single “flash”. Instead, the mask table MT is movable in a given direction (the so-called “scan direction”, e.g. the x direction) with a speed 84, so that the projection beam PB is caused to scan over a mask image; concurrently, the substrate table WT is simultaneously moved in the same or opposite direction at a speed V=Mν, in which M is the magnification of the lens PL (typically, M=¼ or ⅕). In this manner, a relatively large target portion C can be exposed, without having to compromise on resolution.

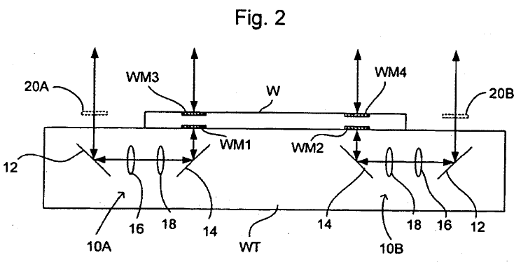

FIG. 2 shows the wafer W on a wafer table WT. Wafer marks WM3 and WM4 are merely optional and provided on the front side of the wafer W. Radiation can be reflected from these marks, as indicated by the arrows above WM3 and WM4, and may be used for alignment with marks on a mask in conjunction with an alignment system (not shown). Wafer marks WM1 and WM2 are provided on the back side of the wafer W. An optical system is built into the wafer table WT for providing optical access to the wafer marks WM1, WM2 on the back side of the wafer W. The optical system comprises a pair of arms 10A, 10B. Each arm consists of two mirrors, 12, 14 and two lenses 16, 18. The mirrors 12, 14 in each arm are inclined such that the sum of the angles that they make with the horizontal is 90°. In this way, a beam of radiation impinging vertically on one of the mirrors will remain vertical when reflected off the other mirror.

In use, radiation is directed from above the wafer table WT onto mirror 12, through lenses 16 and 18, onto mirror 14 and then onto the respective wafer mark WM1, WM2. Radiation is reflected off portions of the wafer mark and returns along the arm of the optical system via mirror 14, lenses 18 and 16 and mirror 12. The mirrors 12, 14 and lenses 16, 18 are arranged such that an image 20A, 20B of the wafer mark WM1, WM2 is formed at the plane of the front (top) side of the wafer W. The order of the lenses 16, 18 and the mirrors 12, 14 can, of course be different, as appropriate to the optical system. For example, lens 18 could be between the mirror 14 and the wafer W.

An image 20A, 20B of a wafer mark WM1, WM2 acts as a virtual wafer mark and can be used for alignment by the pre-existing alignment system (not shown) in exactly the same way as a real wafer mark provided on the front (top) side of the wafer W.

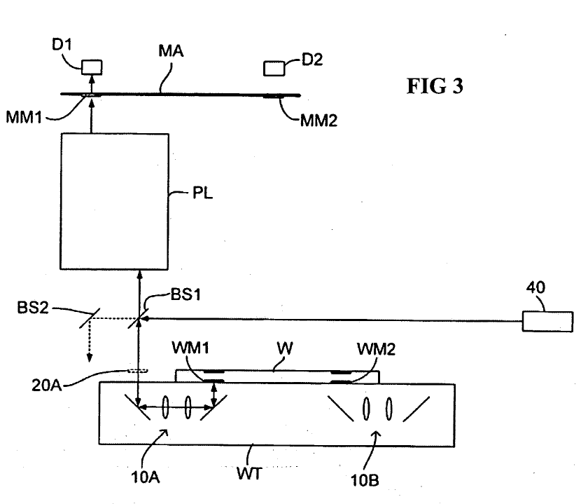

FIGS. 3 and 4 illustrate further aspects of the alignment system. In FIG. 3, a source of radiation, such as a laser 40, e.g. a HeNe laser, directs a beam of alignment radiation onto a first beam splitter BS1, whereby a portion of the radiation is directed down through the arm 10A of the optical system in the wafer table WT, and is reflected off a first wafer mark WM1 on the back side of the wafer W, to form an image 20A of the alignment mark. Radiation from this image 20A passes back through the first beam splitter BS1, through a lens system PL and then through a first mask mark MM1 provided on a mask MA and onto a first detector D1. The signal produced by the detector D1 can be used to determine correct registration between the first mask mark MM1 and the image 20A. The relationship between the image 20A and the wafer mark WM1 is known from the optics 10A, and so alignment between the first mask mark MM1 and the first wafer mark WM1 can be determined. The wafer W and/or mask MA can be moved relative to one another to achieve alignment. The alignment system of this example is a through-the-lens (TTL) arrangement, such that the lens system PL between the mask MA and the wafer W is actually the projection lens used for the exposure radiation. However, the alignment system can also be off-axis (OA).

In FIG. 4, a second wafer mark WM2 is aligned with a second mask mark MM2, using a second beam splitter BS2 and the other arm 10B of the optical system. The process can be repeated to align, for example, the first mask mark MM1 with the second wafer mark WM2 and so on.

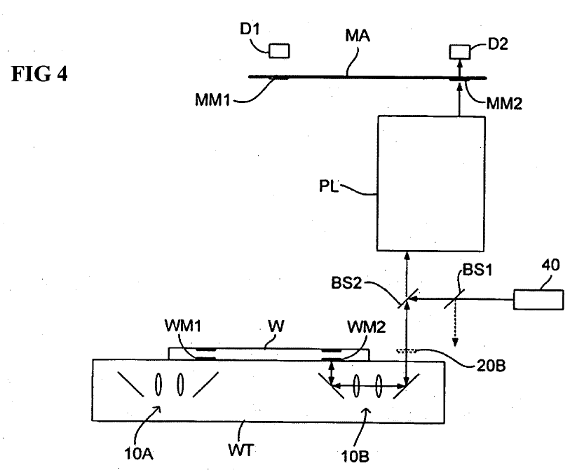

FIG. 5 shows an embodiment of an alignment mark comprising a phase grating. Such a grating may consist of four subgratings P_{1,a}, P_{1,b}, P_{1,c} and P_{1,d}, two of which, P_{1,b} and P_{1,d}, serve for alignment in the X direction and the two other ones, P_{1,a} and P_{1,c} serve for alignment in the Y direction.

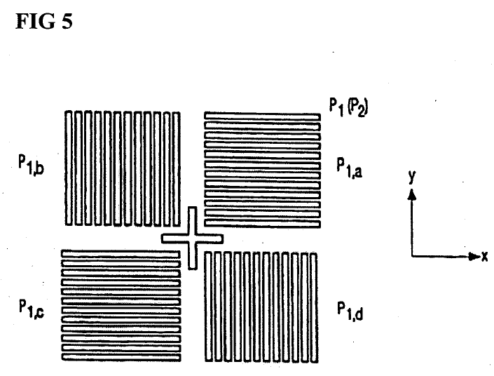

FIG. 6 shows an arrangement similar to the systems in FIG. 2, except that the arms of the optical system 10A, 10B are arranged to image wafer marks WM3 and WM4, which are on the front side of a substrate according to the present invention, e.g. wafer W, by transmitting radiation through the substrate via the back side of the substrate. For example, in the case of a silicon wafer, infrared radiation may be used in the alignment system because silicon is transmissive to infrared radiation. This embodiment may be used with further wafer marks on the back side of the substrate, but using wafer markers on the front side means that it is not necessary to process the back side of the wafer to provide wafer marks, unless desired.

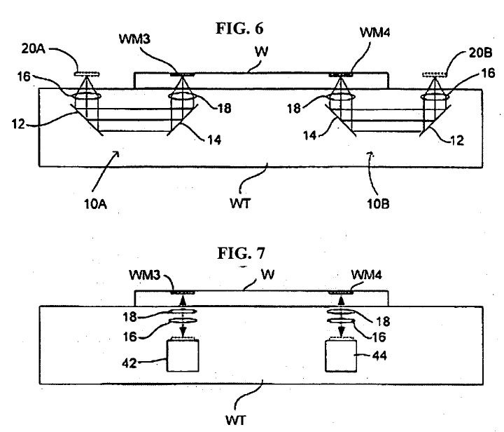

FIG. 7 shows a further embodiment in which alignment radiation is transmitted through a substrate according to the present invention, e.g. the wafer W, via the back side of the substrate to marks WM3, WM4 on the front side, and detectors 42, 44 in the substrate table WT derive the location of the alignment marks on the substrate relative to the substrate table WT.

Some examples of devices that can be created with the present substrates, for instance wafers, e.g. via lithography, include micro electromechanical systems “MEMS”), thin film heads, integrated passive components, image sensors, and integrated circuits (ICs) including, e.g., power ICs, analog ICs, and discrete ICs. These devices in turn find many applications. For instance, image sensors (e.g. CCD or CMOS image sensors) may be used in cameras, integrated circuits may be used in telecommunications equipment (e.g. mobile phones) or computers, etc.

Having described specific embodiments of the present invention, it will be understood that many modifications thereof will readily appear or may be suggested to those skilled in the art, and it is intended therefore that this invention is limited only by the spirit and scope of the following claims.

What is claimed is:

1. A semiconductor wafer having a front side and a back side, said front side having a smoother surface than said back side, wherein said back side comprises one or more alignment marks.

2. The wafer of claim 1, wherein said front side comprises alignment marks.

3. The wafer of claim 1, wherein said front side is absent alignment marks.

4. The wafer of claim 1, wherein said back side has a surface roughness of less than 600 nm.

5. The wafer of claim 1, wherein said back side has a surface roughness of at least 50 nm.

6. The wafer of claim 1, wherein said back side has a surface roughness of in the range of 100-400 nm.

7. The wafer of claim 1, wherein said wafer is a single side polished wafer.

8. The wafer of claim 1, wherein the difference in surface roughness between said front side and said backside is obtained by polishing the front side and the back side to different degrees.

9. The wafer of claim 1, wherein the one or more back side alignment marks comprise a grating.

10. The wafer of claim 1, wherein said one or more alignment marks have a pitch depth in the range of 100-300 nm.

11. The wafer of claim 1, wherein said front side is sufficiently smooth for the lithographic creation of micro circuit patterns on said front side.

12. The wafer of claim 1, wherein said back side is insufficiently smooth for the lithographic creation of micro circuit patterns on said back side.

13. The wafer of claim 1, wherein said wafer is made from material selected from the group consisting of Si, SiGe, SiGeC, SiC, Ge, GaAs, InP, and InAs.

14. The wafer of claim 1, wherein said wafer is a silicon wafer.

15. The wafer of claim 1, wherein said wafer has a diameter in the range of 50-150 mm.

16. The wafer of claim 1, wherein said wafer has a diameter of about 200 mm or about 300 mm.

17. A wafer of claim 1, wherein a resist coating is provided on said front side.

18. A process comprising:
(i) patterning a beam of radiation; and
(ii) exposing at least part of said resist coating of said wafer according to claim 17 to said patterned beam of radiation.

19. The process of claim 18, wherein said patterning is effected with a reticle or an array of individually programmable elements.

20. The process of claim 19 further comprising aligning said reticle or said array to said wafer using the one or more backside alignment marks.

21. A device obtained with the process of claim 18.

22. The device of claim 21, wherein said device is selected from the group consisting of micro electromechanical systems, thin film heads, image sensors, and integrated circuits.

23. A semiconductor wafer having a front side and a back side, said front side having a surface roughness of less than 50 nm, said back side having a surface roughness in the range of 75-250 nm.

24. A lithography process comprising:
(i) aligning a substrate having a front side and a back side to a reticle or an array of individually programmable elements;
(ii) patterning a beam of radiation with said reticle or said array of individually programmable elements; and
(ii) exposing the front side of said substrate, or a resist layer provided on said front side of said substrate, to the patterned beam of radiation;
wherein said front side has a smoother surface than said back side;
wherein said front side comprises one or more alignment marks;
wherein said aligning is effected by imaging one or more of said one or more alignment marks via the back side of the wafer.

25. The process of claim 24, wherein said substrate is a silicon substrate.

26. The process of claim 24, wherein said imaging is effected using infrared radiation.

27. The process of claim 24, wherein said back side has a surface roughness of at least 100 nm.

28. A process comprising providing the back side of a substrate having a front side and a back side with one or more alignment marks, wherein said front side has a smoother surface than said back side.

29. The process of claim 28, wherein said process is a lithographic process.

30. The process of claim 28, wherein said process comprises applying a layer of resist on said front side.
